(19) United States
(12) Patent Application Publication
(10) Pub. No.: US 2012/0037208 A1
(43) Pub. Date: Feb. 16, 2012

(54) THIN FILM SOLAR CELL STRUCTURE

(75) Inventor: Martin Tze Wei Ang, Singapore (SG)

(73) Assignee: AGENCY FOR SCIENCE, TECHNOLOGY AND RESEARCH, Singapore, SG (SG)

(21) Appl. No.: 13/147,592

(22) PCT Filed: Feb. 2, 2010
(86) PCT No.: PCT/SG10/00031

§ 371 Date: Oct. 18, 2011

(30) Foreign Application Priority Data
Feb. 2, 2009 (SG) 200900696-6

(51) Int. Cl. H01L 31/0232; H01L 31/04

(52) U.S. Cl. 136/246; 438/69; 257/E31.127

(57) ABSTRACT

A thin film solar cell structure and method of fabricating a thin film solar cell structure. The thin film solar cell structure comprises a photoelectric conversion structure; a grating coupler for coupling incident light into the photoelectric conversion structure; and a resonator structure for providing a light trapping in the photoelectric conversion structure.

### FIELD OF INVENTION

The present invention relates to a thin film solar cell and a method of fabricating a thin film solar cell.

### BACKGROUND

Silicon (Si) and Amorphous Silicon (a-Si) solar cells have dominated the photovoltaic (PV) industry as they are compatible with existing semiconductor technologies which has translated to cost savings in manufacturing. The prevalence of Si and a-Si solar cells can also be attributed to the low cost of Si and a-Si and their relative stability when compared with other types of solar cells such as III-V solar concentrators.

However, Si and a-Si solar cells suffer from poor conversion efficiency in that they are unable to efficiently convert the incident light into electricity. For example, the conversion efficiencies of typical commercially produced silicon and amorphous silicon solar cells are no higher than 20% and 10% respectively. As such, there is room to improve the performance efficiency of the Si and a-Si solar cells.

Therefore, there exists a need to provide a thin film solar cell and method of fabricating a thin film solar cell to address one or more of the problems mentioned above.

### SUMMARY

In accordance with a first aspect of the present invention, there is provided a thin film solar cell structure comprising: a photoelectric conversion structure; a grating coupler for coupling incident light into the photoelectric conversion structure; and a resonator structure for providing a light trapping in the photoelectric conversion structure.

The thin film solar cell structure may further comprise a cladding structure for providing guided waves in the photoelectric conversion structure.

The photoelectric conversion structure may be Si (Silicon) or a-Si (Amorphous Silicon) based.

The thin film solar cell structure may further comprise a reflector structure for reflecting leakage light which escape the photoelectric conversion structure, back into the photoelectric conversion structure.

The photoelectric conversion structure may have a thickness of about 1 micron or less.

The grating coupler may comprise any one of asymmetrical blazed, pyramid or sawtooth shaped.

The grating coupler may comprise of symmetrical sinusoidal or rectangular shaped.

The grating coupler may have a grating period in a range of about 400 nm to 1500 nm, and a grating height of about 10 nm to 300 nm;

The grating coupler may provide a textured surface for reducing the reflection of normal incident light.

The grating coupler may be optimized to increase absorption of infrared wavelengths.

The grating coupler may be optimized to reduce absorption of ultra-violet rays.

The grating coupler may be chirped or circular for focusing of incident light into an active area of the photoelectric conversion structure.

The resonator structure may comprise a pair of surface and buried resonator layers.

The surface resonator layer may comprise an anti-reflection coating.

The anti-reflection coating may comprise Si₃N₄.

The surface and buried resonator layers may comprise respective silicon dioxide (SiO₂) layers.

The thickness of the buried resonator layer may be about 670-1200 nm.

The reflector structure may comprise a substrate reflector.

The substrate reflector may comprise a layer of Aluminum or Silver

The cladding structure may comprise silicon dioxide layers.

The photoelectric conversion structure may be configured as a plasmonic-enhanced device.

In accordance with a second aspect of the present invention there is provided a method of fabricating a thin film solar cell structure, the method comprising forming a photoelectric conversion structure; forming a grating coupler for coupling incident light into the photoelectric conversion structure; and forming a resonator structure for providing a light trapping in the photoelectric conversion structure.

The method may further comprise forming a cladding structure for providing guided waves in the photoelectric conversion structure.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a thin film silicon solar cell structure in an example embodiment of the present invention.

FIG. 2 shows a thin film amorphous silicon solar cell structure in an example embodiment of the present invention.

FIG. 3 shows a flowchart illustrating a method of fabricating a thin film solar cell structure according to an example embodiment.

### DETAILED DESCRIPTION

Embodiments of the present invention seek to improve the performance of output conversion efficiencies of e.g. silicon or amorphous silicon solar cells by optical means.

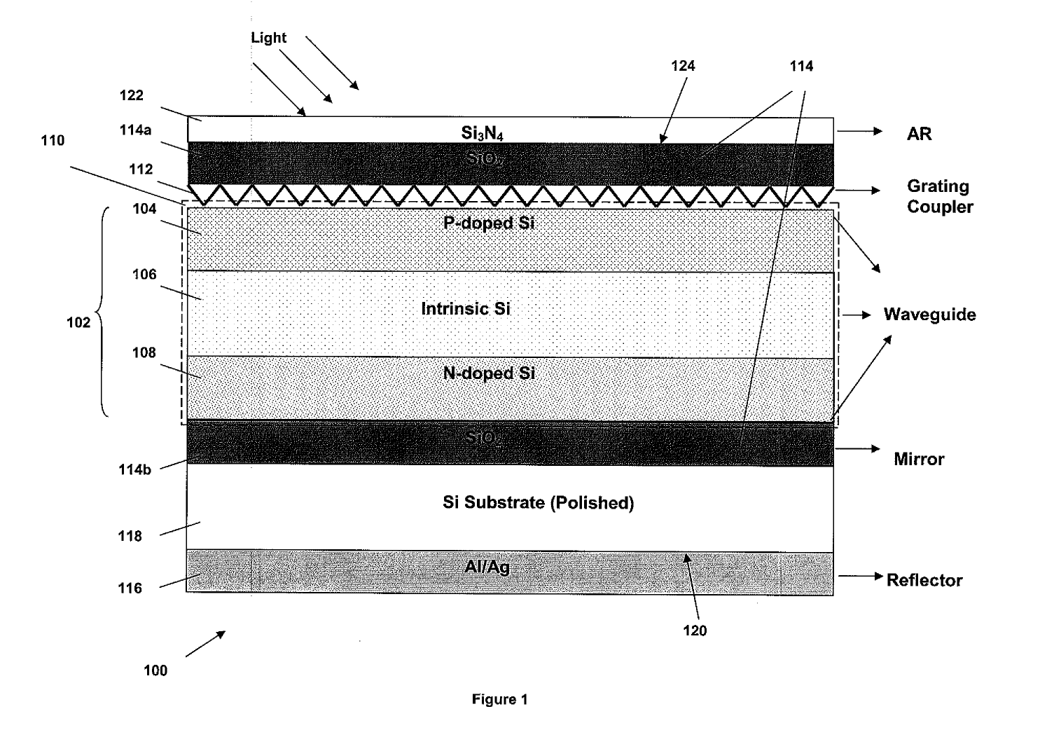

FIG. 1 shows a thin film solar cell structure 100 in an example embodiment of the present invention. The solar cell structure 100 comprises a photoelectric conversion structure 102 having a p-type Si layer 104, an i-type layer Si 106, and an n-type Si layer 108 forming an active region/area 110.

In the example embodiment, the structure 100 further comprises a grating coupler 112 for coupling incident light into the active area 110, serving as means for optical absorption. The grating coupler 112 is also capable of coupling infrared light into the active area 110. In the example embodiment of the solar cell structure 100 illustrated in FIG. 1, the grating coupler 112 is a blaze grating coupler. It will be appreciated by a person skilled in the art that grating couplers may also be referred to as photonics crystals.

In the example embodiment, the photoelectric conversion structure 102 is selected to be of a compound of sufficiently higher optical density compared with its surrounding layers e.g. 114a, 114b such that the photoelectric conversion structure 102 can also serve as a waveguide to provide better confinement of light within the active area 110.

Further, the solar cell structure 100 further comprises a resonator structure 114 for amplifying light within the active area 110. This resonator structure 114 comprises a surface resonator layer 114a and a buried resonator layer 114b of e.g. silicon dioxide (SiO₂) sandwiching the photoelectric conversion structure 102 and grating coupler 112. Collectively, the surface resonator layer 114a and buried resonator layer 114b form a resonance cavity to provide resonance of light and hence “light trapping” to increase the optical absorption within the active area.

Additionally, in the example embodiment, the solar cell structure 100 further comprises a substrate reflective layer 116 coated on a face 120 of a substrate 118 opposite that of the face in contact with the buried resonator layer 114b. The substrate reflective layer 116 is a layer of e.g. Al (aluminium) or Ag (silver) in non-limiting example embodiments and can reflect leakage light, which has escaped the active area 110 through the buried resonator layer 114b into the substrate 118, back into the active area 110. Further, a surface anti-reflective layer 122 of e.g. Si₃N₄, is coated on the outer surface 124 of the resonator layer 114a to provide anti-reflection (AR). This AR layer 122 serves to prevent incident light from being reflected off the solar cell structure 100.

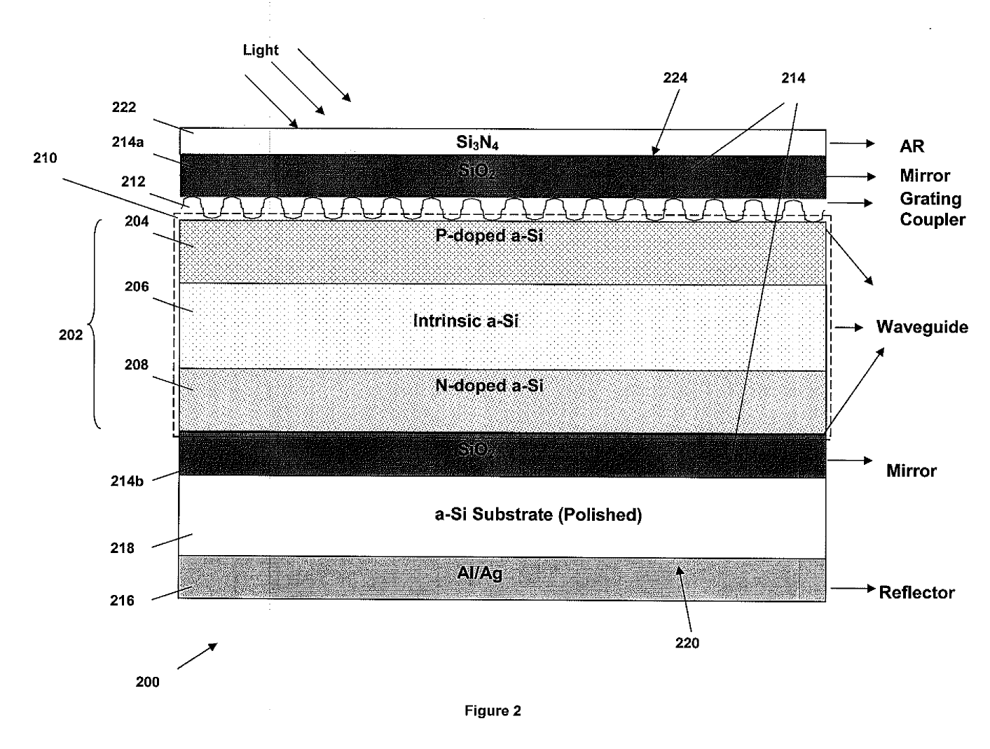

The solar cell structure 100 described in FIG. 1 comprises silicon solar cells. A similar solar cell structure may also be applicable to amorphous silicon solar cells. In another example embodiment shown in FIG. 2, the silicon solar cell structure 200 comprises a photoelectric conversion structure 202 having a p-type a-Si layer 204, an i-type layer a-Si 206, and an n-type a-Si layer 208 forming an active region/area 210.

In the example embodiment, the structure 200 further comprises a grating coupler 212 for coupling incident light into the active area 210, serving as means for optical absorption. The grating coupler 212 is also capable of coupling infrared light into the active area 210. In the example embodiment of the silicon solar cell structure 200 illustrated in FIG. 2, the grating coupler 212 is a sinusoidal grating coupler.

In the example embodiment, the photoelectric conversion structure 202 is selected to be of a compound of sufficiently higher optical density compared with its surrounding layers e.g. 214a, 214b such that the photoelectric conversion structure 202 can also serve as a waveguide to provide better confinement of light within the active area 210.

Further, the structure 200 further comprises a resonator structure 214 for amplifying light within the active area 210. This resonator structure 214 comprises a surface resonator layer 214a and a buried resonator layer 214b of e.g. silicon dioxide (SiO₂) sandwiching the photoelectric conversion structure 202 and grating coupler 212. Collectively, the surface resonator layer 214a and buried resonator layer 214b form a resonance cavity to provide resonance of light and hence “light trapping” to increase the optical absorption within the active area.

Additionally, in the example embodiment, the structure 200 further comprises a substrate reflective layer 216 coated on a face 220 of a substrate 218 opposite that of the face in contact with the buried resonator layer 214b. The substrate reflective layer 216 is a layer of e.g. Al (aluminium) or Ag (silver) and can reflect leakage light, which has escaped the active area 210 through the buried resonator layer 214b into the substrate 218, back into the active area 210. Further, a surface anti-reflective layer 222 of e.g. Si₃N₄, is coated on the outer surface 224 of the resonator layer 214a to provide anti-reflection (AR). This AR layer 222 serves to prevent incident light from being reflected off the solar cell structure 200.

The embodiments of the present invention describe thin-film (<1 μm) silicon and amorphous silicon (a-Si) solar cells whose base material is silicon-on-insulator (SOD. However, it will be appreciated by a person skilled in the art that the embodiments of the present invention can also apply to other base materials such as crystalline silicon (c-Si) and poly-silicon (poly-Si).

With reference to FIGS. 1 and 2, the embodiments of the present invention include grating coupler 112/212 which couples incident light more efficiently into the solar cells, hence increases the efficiency (by having more light going into the active region). Optimised SOI grating couplers can provide a coupling efficiency of 70% and >80% for rectangular gratings and blaze gratings, respectively. The grating couplers can be designed by using the formula of

$$sin φ = N - \frac{λ}{d}$$

where φ is the angle of incident light, N is the effective refractive index of the waveguide guiding layer, λ is the incidence light wavelength and d is the grating period. In the example embodiments, the grating period is optimized for the silicon solar cell structure 100 and the a-Si solar cell structure 200, to cater for wavelengths at near infrared sunlight (but not limited to), since silicon by itself is already a good optical absorber of visible wavelengths (400 nm to 800 nm). Also, the grating period is preferably chosen so as to reduce absorption of ultra-violet rays.

The blaze grating coupler 112 (FIG. 1) or sinusoidal grating couplers 212 (FIG. 2) both also provide a “textured surface” to reduce the reflection of normal incident light. The gratings can be mass produced using wet chemical etching or holographic lasers which are industrially compatible. The grating height, in this case for the silicon solar cell structures 100 and 200, is optimized in an embodiment at about 100±10% nm which can be produced by wet chemical etching or dry reactive ion etching (RIE).

In the example embodiments, the thin-film silicon or a-Si core layers such as the photoelectric conversion structure 102/202 are designed with 1 μm thickness (and below) to provide confinement of guided waves (converted from the incident light) due to the high refractive index difference of e.g. about 2.1 for Si/SiO₂. As such, the photoelectric conversion structure 102/202 may also be referred to as a waveguide layer.

The confinement of the light in the active area 110/210 in the example embodiments is further enhanced by the surface and buried silicon dioxides 114a/214a, 114b/214b. These SiO₂ layers 114a/214a, 114b/214b, serve as a pair of mirrors or resonator layers that provide resonance of light—hence “light trapping” to increase the optical absorption, which is not readily obtained in existing thin-film solar cells. The same buried oxide (resonator) layer 114b/214b which is optimized at the thickness of about 0.67±10% μm and the coated metal layer 120/220 of e.g. Al/Ag in one embodiment can reflect most of the light or leakage light back to the active area 110/210 to further increase the efficiency of solar cells. The surface oxide layer 114a/214a may be coated with an anti-reflection (AR) coating of e.g. Si₃N₄ which has a refractive index of about 2.2

The embodiments of the present invention harness existing microelectronics technology and inexpensive silicon material complementing with silicon photonics, to further reduce the cost of fabricating solar cells with increased solar efficiency. The embodiments described can allow monolithic integration of optical components to provide robustness of manufacturing of the solar cells in volume, as well as miniaturizing the solar cell modules using the solution of low cost silicon CMOS technology. A low cost solution for solar cells using low cost silicon material and existing CMOS technology can therefore be provided. The embodiments also incorporate monolithic integration of grating couplers, reflectors and mirrors in Si and/or a-Si solar cell structures.

In the example embodiments, the photoelectric conversion structure may be a p-i-n photo detector or photodiode. The embodiments of the present invention may therefore comprise a solar cell structure that comprises a p-i-n photodetector or photodiode which can also serve as an optical waveguide layer, a grating coupler, a vertical resonator, and a substrate reflector.

In the example embodiments, the substrate reflector may comprise silicon-on-insulator (SOI), amorphous silicon (a-Si) and/or poly silicon (poly-Si). The photoelectric conversion structure which also serves as a waveguide layer may have a thickness of about 1 micron or less.

The grating coupler in the example embodiments may be asymmetrical blazed, pyramid or sawtooth shaped. Alternatively, the grating coupler may be symmetrical sinusoidal and rectangular shaped. Further, the grating coupler may have a grating period in the range of about 400 nm to 1500 nm, with a grating height of about 10 nm to 300 nm. In addition, the grating coupler may provide a textured surface and such that infrared light is coupled into the active area, improving the optical absorption in the thin-film solar cells and hence increasing the efficiency of solar cells. The efficiency of solar cells may also be increased through a grating coupler that is chirped or circular to enable focusing of incident light into the p-i-n active area.

The vertical resonator in the example embodiments may comprise a pair of surface and buried silicon dioxide layers sandwiching the photoelectric conversion structure (and, if present, the grating coupler) for providing resonance of light and hence “light trapping” to increase the optical absorption and thus the efficiency of the solar cells.

The surface resonator layer of the resonator in the example embodiment may be first coated with a layer of silicon nitride (Si₃N₄) to provide an anti-reflection coating.

In the example embodiments, the thickness of the buried resonator (oxide) layer in SOI may be about 670-1200 nm. The substrate reflector may be a layer of e.g. Al or Ag and is capable of reflecting leakage light which escape the active area into the substrate, back into the active area, thus increasing the efficiency of the solar cells;

The optical waveguide layer in the example embodiments may be referred to as a core waveguide silicon layer. It will be appreciated that un-doped silicon in SOI may already serve as a core waveguide layer. Subsequent doping of this silicon core waveguide layer to form e.g. the p-i-n active area (comprising the intrinsic layer, p-type layer and n-type layer) can transform the silicon layer into a photodetector (solar cell), capable of converting light into electricity. The core waveguide silicon layer (or p-i-n active area in this example), interfaces with silicon dioxide cladding layers to provide a confinement of light in the p-i-n active area (light trapping), and hence increasing the efficiency of solar cells.

It will be appreciated by a person skilled in the art that in the example embodiments, the metal contact or core layer of the p-i-n photodetector or photodiode can be implanted with impurities as plasmonic-enhanced device, hence increasing the efficiency of solar cells. Alternatively, a single metal layer or metal gratings can be fabricated on the device or embedded within the device to induce a plasmonic effect which thus increases the efficiency of the solar cell. The metal layer or metal gratings can for example be formed by sputtering, deposition, wafer bonding or lithography.

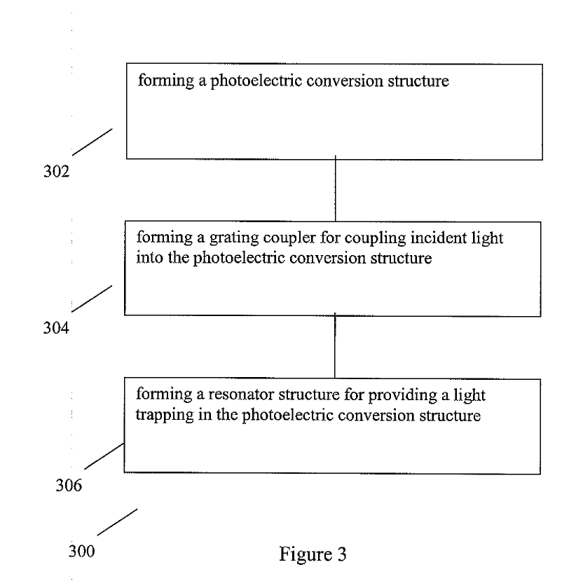

FIG. 3 shows a flowchart 300 illustrating a method of fabricating a thin film solar cell structure according to an example embodiment. At step 302, a photoelectric conversion structure is formed. At step 304, a grating coupler for coupling incident light into the photoelectric conversion structure is formed. At step 306, a resonator structure for providing a light trapping in the photoelectric conversion structure is formed. The method may further comprise forming a cladding structure for providing guided waves in the photoelectric conversion structure. A number of different thin film fabrication and processing techniques may be used to implement the method in example embodiments. Those techniques are understood in the art and will not be described herein in any detail.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A thin film solar cell structure comprising:
a photoelectric conversion structure;
a grating coupler for coupling incident light into the photoelectric conversion structure; and
a resonator structure for providing a light trapping in the photoelectric conversion structure.

2. The thin film solar cell structure as claimed in claim 1 further comprising a cladding structure for providing guided waves in the photoelectric conversion structure.

3. The thin film solar cell structure as claimed in claim 1, wherein the photoelectric conversion structure is Si (Silicon) or a-Si (Amorphous Silicon) based.

4. The thin film solar cell structure as claimed in claim 1, further comprising a reflector structure for reflecting leakage light which escape the photoelectric conversion structure, back into the photoelectric conversion structure.

5. The thin film solar cell structure as claimed in claim 1 wherein the photoelectric conversion structure has a thickness of about 1 micron or less.

6. The thin film solar cell structure as claimed in claim 1 wherein the grating coupler comprises any one of asymmetrical blazed, pyramid or sawtooth shaped.

7. The thin film solar cell structure as claimed in claim 1 wherein the grating coupler comprises any one of symmetrical sinusoidal or rectangular shaped.

8. The thin film solar cell structure as claimed in claim 1 wherein the grating coupler has a grating period in a range of about 400 nm to 1500 nm, and a grating height of about 10 nm to 300 nm.

9. The thin film solar cell structure as claimed in claim 1 wherein the grating coupler provides a textured surface for reducing the reflection of normal incident light.

10. The thin film solar cell structure as claimed in claim 1 wherein the grating coupler is optimized to increase absorption of infrared wavelengths.

11. The thin film solar cell structure as claimed in claim 1 wherein the grating coupler is optimized to reduce absorption of ultra-violet rays.

12. The thin film solar cell structure as claimed in claim 1 wherein the grating coupler is chirped or circular for focusing of incident light into an active area of the photoelectric conversion structure.

13. The thin film solar cell structure as claimed in claim 1 wherein the resonator structure comprises a pair of surface and buried resonator layers.

14. The thin film solar cell structure as claimed in claim 13 wherein the surface resonator layer comprises an anti-reflection coating.

15. The thin film solar cell structure as claimed in claim 14 wherein the anti-reflection coating comprises Si₃N₄.

16. The thin film solar cell structure as claimed in claim 13, wherein the surface and buried resonator layers comprises respective silicon dioxide (SiO₂) layers.

17. The thin film solar cell structure as claimed in claim 13 wherein the thickness of the buried resonator layer is about 670-1200 nm.

18. The thin film solar cell structure as claimed in claim 4, wherein the reflector structure comprises a substrate reflector.

19. The thin film solar cell structure as claimed in claim 18, wherein the substrate reflector comprises a layer of Aluminum or Silver

20. The thin film solar cell structure as claimed in claim 2 wherein the cladding structure comprises silicon dioxide layers.

21. The thin film solar cell structure as claimed in claim 1 wherein the photoelectric conversion structure is configured as a plasmonic-enhanced device.

22. A method of fabricating a thin film solar cell structure, the method comprising:
forming a photoelectric conversion structure;
forming a gating coupler for coupling incident light into the photoelectric conversion structure; and
forming a resonator structure for providing a light trapping in the photoelectric conversion structure.

23. The method as claimed in claim 22, further comprising forming a cladding structure for providing guided waves in the photoelectric conversion structure.
